(19) United States
(12) Patent Application Publication
(10) Pub. No.: US 2014/0138819 A1
(43) Pub. Date: May 22, 2014

(54) SEMICONDUCTOR DEVICE INCLUDING TSV AND SEMICONDUCTOR PACKAGE INCLUDING THE SAME

(71) Applicant: Samsung Electronics Co., Ltd., Suwon-si (KR)

(72) Inventors: Ju-il Choi, Suwon-si (KR); Su-kyung Kim, Suwon-si (KR); Kun-sang Park, Hwaseong-si (KR); Seong-min Son, Hwaseong-si (KR); Jin-ho An, Seoul (KR); Do-sun Lee, Gwangju (KR)

(73) Assignee: Samsung Electronics Co., Ltd., Suwon-si (KR)

(21) Appl. No.: 14/074,573

(22) Filed: Nov. 7, 2013

(30) Foreign Application Priority Data
Nov. 21, 2012 (KR) 10-2012-0132601

(51) Int. Cl. H01L 23/48

(52) U.S. Cl. CPC H01L 23/481
USPC 257/737; 257/774

(57) ABSTRACT

Provided are a semiconductor device, a method of manufacturing the same, and a semiconductor package including the same. The semiconductor device includes: a substrate having a recess region in a predetermined portion of a back side of the substrate; a wiring part disposed on a front side of the substrate and including at least one wiring layer; an insulating layer disposed on the back side of the substrate and including a first portion filling in the recess region and a second portion covering the back side of the substrate of a non-recess region other than the recess region; and a through silicon via (TSV) provided in plurality of and penetrating the first portion to be electrically connected to the at least one wiring layer.

### CROSS-REFERENCE TO RELATED APPLICATIONS

This application claims the benefit of Korean Patent Application No. 10-2012-0132601, filed on Nov. 21, 2012, in the Korean Intellectual Property Office, the disclosure of which is incorporated herein in its entirety by reference.

### BACKGROUND

The inventive concept relates to a semiconductor device, and more particularly, to a semiconductor device, a method of manufacturing the same, and, a semiconductor package including the same.

In general, various semiconductor processes are performed on a wafer to form a plurality of semiconductor chips. Then, to mount each semiconductor chip on a printed circuit board (PCB), a packaging process is performed on the wafer to form a semiconductor package. The semiconductor package may include a semiconductor chip, a PCB having a chip mounted thereon, a bonding wire or bump that electrically bonds the semiconductor chip with the PCB, and a sealing material sealing the semiconductor chip.

Semiconductor packages, in which semiconductor devices are stacked using a through silicon via (TSV), have recently been introduced. In relation to a stacked chip package using a TSV, the TSV is formed in a chip and a plurality of chips are physically and electrically stacked and connected by such a TSV.

### SUMMARY

The inventive concept provides a semiconductor device in which a TSV is efficiently formed and an insulating layer surrounding the TSV is formed with a sufficient thickness as the size of a device is reduced, a method of manufacturing the same, and a semiconductor package including the same.

According to an aspect of the inventive concept, there is provided a semiconductor device including: a substrate having a recess region in a predetermined portion of a back side of the substrate; a wiring part disposed on a front side of the substrate and including at least one wiring layer; an insulating layer disposed on the back side of the substrate and including a first portion filling in the recess region and a second portion covering the back side of the substrate of a non-recess region other than the recess region; and a through silicon via (TSV) provided in plurality of and penetrating the first portion to be electrically connected to the at least one wiring layer.

The wiring part may include at least two wiring layers, and the TSV is connected to a wiring layer that is the most adjacent to the insulating layer.

The semiconductor device may have a rectangle portion that is horizontally shaped; and a horizontal section of the recess region may have one of a rectangular ring form surrounding an outer border portion of the rectangle portion, an elongated rectangular form extending from a center portion of the rectangle portion, two elongated rectangular forms extending along both sides of the rectangle portion, a central rectangular form, and a form including a central rectangle and a rectangular ring surrounding the central rectangle.

At least one interlayer insulating layer may be disposed between the at least one wiring layer and the insulating layer, and a first interlayer insulating layer contacting the insulating layer may have an etch selectivity different than an etch selectivity of the insulating layer.

When the insulating layer is an oxide layer, the first interlayer insulating layer may be a nitride layer, and when the insulating layer is a nitride layer, the first interlayer insulating layer may be an oxide layer.

A bottom surface of the TSV may face in a same direction as the back side of the substrate and may be exposed at the first portion; and a bump or a pad and a bump may be disposed on the bottom surface of the TSV.

A bottom surface of the insulating layer facing the same direction as the back side of the substrate and the bottom surface of the TSV may form a same plane.

A bottom surface of the TSV may face a same direction as the back side of the substrate and may be exposed at the first portion;

A pad and a bump may be disposed on the insulating layer at a portion spaced a predetermined distance apart from a bottom surface of the TSV; and the pad and the bottom surface of the TSV may be connected to each other through a rewiring line.

A resist layer covering the rewiring line and exposing the bump may be formed on the insulating layer.

The second portion of the insulating layer may serve as a protective layer protecting the back side of the substrate of the non-recess region.

According to another aspect of the inventive concept, there is provided a semiconductor package including: a first semiconductor chip including the semiconductor device; at least one second semiconductor chip stacked on the first semiconductor chip; and a sealing material sealing the first semiconductor chip and the at least one second semiconductor chip, wherein the TSV is electrically connected to the at least one second semiconductor chip.

The at least one second semiconductor chip may be provided in plurality, and the TSV may be formed in a remaining second semiconductor chip except the uppermost second semiconductor chip among the at least one semiconductor chip provided in plurality.

An electrode pad may be formed in the first semiconductor chip; an external connection member may be disposed on the electrode pad; and the first semiconductor chip may be mounted on a main chip or a package substrate, which supports the semiconductor package, through the external connection member.

According to another aspect of the inventive concept, there is provided a semiconductor device including: a substrate having a front side and a back side and including a recess region in a predetermined portion of the back side; an insulating layer filling in the recess region and covering an entirety of the back side of the substrate; and a plurality of TSVs formed by penetrating the insulating layer in the recess region, electrically insulated from the substrate, and electrically connected to a wiring layer on the substrate.

A barrier layer may be formed between the plurality of TSVs and the insulating layer.

### BRIEF DESCRIPTION OF THE DRAWINGS

Exemplary embodiments of the inventive concept will be more clearly understood from the following detailed description taken in conjunction with the accompanying drawings in which:

FIGS. 1 to 4 are cross-sectional views of a semiconductor device including a through silicon via (TSV) according to embodiments of the inventive subject matter.

FIGS. 5A to 5F are cross-sectional views illustrating a method of manufacturing a semiconductor device including the TSV of FIG. 1 according to embodiments of the inventive subject matter.

FIG. 6 is a detailed cross-sectional view illustrating the structure of a TSV in a semiconductor device including the TSV of FIG. 1 according to embodiments of the inventive subject matter.

FIGS. 7A-7C are cross-sectional views illustrating a method of manufacturing a semiconductor device including the TSV of FIG. 2 according to embodiments of the inventive subject matter.

FIG. 8 is a cross-sectional view illustrating a method of manufacturing a semiconductor device including the TSV of FIG. 3 according to embodiments of the inventive subject matter.

FIGS. 9A and 9B are cross-sectional views illustrating a method of manufacturing a semiconductor device including the TSV of FIG. 4 according to embodiments of the inventive subject matter.

FIGS. 10A to 10E are plan views of a region having a TSV according to embodiments of the inventive subject matter.

FIGS. 11 to 13 are cross-sectional views of a semiconductor package according to embodiments of the inventive subject matter;

FIG. 14 is a block diagram illustrating a memory card including a semiconductor package according to some embodiments of the inventive subject matter.

FIG. 15 is a block diagram illustrating an electronic system including a semiconductor package according to some embodiments of the inventive subject matter.

### DETAILED DESCRIPTION OF THE EMBODIMENTS

Hereinafter, preferred embodiments will be described in more detail with reference to the accompanying drawings.

The invention may, however, be embodied in many different forms and should not be construed as being limited to the embodiments set forth herein; rather, these embodiments are provided so that this disclosure will be thorough and complete, and will fully convey the concept of the invention to those skilled in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

It will be also understood that although the terms first, second, third etc, may be used herein to describe various elements, these elements should not be limited by these terms. These terms are only used to distinguish one element from another element. Thus, a first element in some embodiments could be termed a second element in other embodiments without departing from the teachings of example embodiments of inventive concepts. Aspects of example embodiments of inventive concepts explained and illustrated herein include their complementary counterparts. The same reference numerals or the same reference designators denote the same elements throughout the specification.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and this specification and will not be interpreted in an idealized or overly formal sense unless expressly so defined herein.

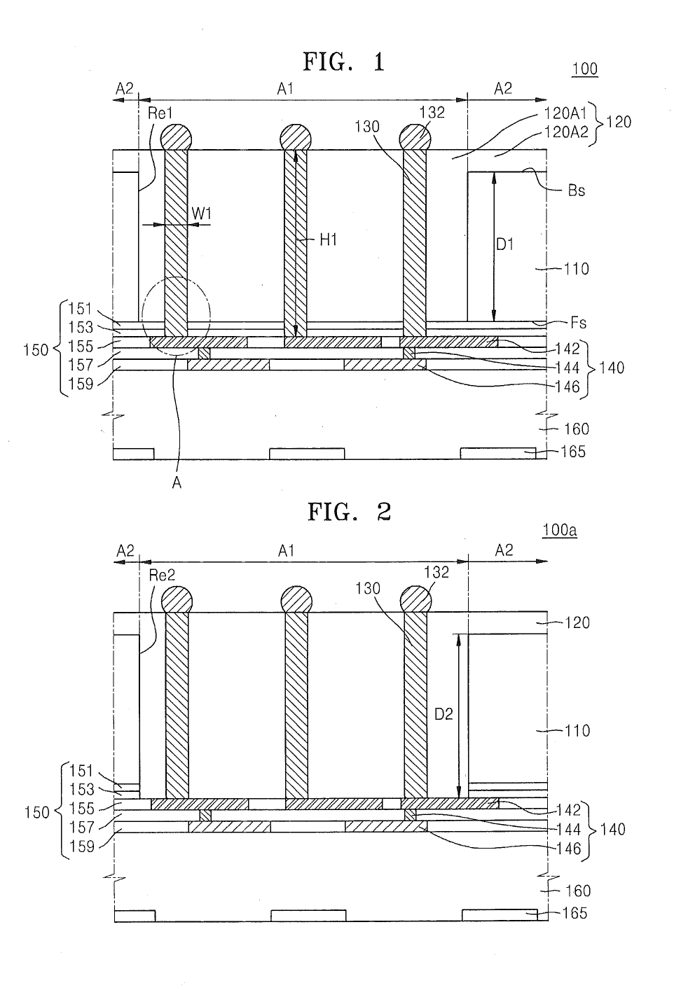

FIGS. 1 to 4 are cross-sectional views of a semiconductor device including a through silicon via (TSV) according to embodiments of the inventive subject matter.

Referring to FIG. 1, the semiconductor device 100 may include a substrate 110, an insulating layer 120, a TSV 130, a wiring part 140, an interlayer insulating layer part 150, and a lower layer 160.

The substrate 110 may be a semiconductor substrate formed of a semiconductor material. For example, the substrate 110 may include a group IV material or a group III-V compound. Moreover, the substrate 110 may be formed of a single crystal wafer, such as a silicon single crystal wafer. However, the substrate 110 is not limited to a single crystal wafer. Therefore, various wafers such as an Epi or Epitaxial wafer, a polished wafer, an annealed wafer, and a silicon on insulator (SOI) wafer may be used as the substrate 110. Here, the Epitaxial wafer refers to a wafer formed by growing a crystalline material on a single crystal silicon substrate.

The substrate 110 may include a front side Fs and a back side Bs, and an integrated circuit layer (not shown) may be formed on the front side Fs of the substrate 110. Accordingly, the front side Fs of the substrate 110 may be referred to as an active surface. Doping regions doped with an impurity may be formed at the bottom region of the substrate 110 adjacent to the front side Fs. Moreover, the top region of the substrate 110 adjacent to the back side Bs opposite to the front side Fs may be an undoped region.

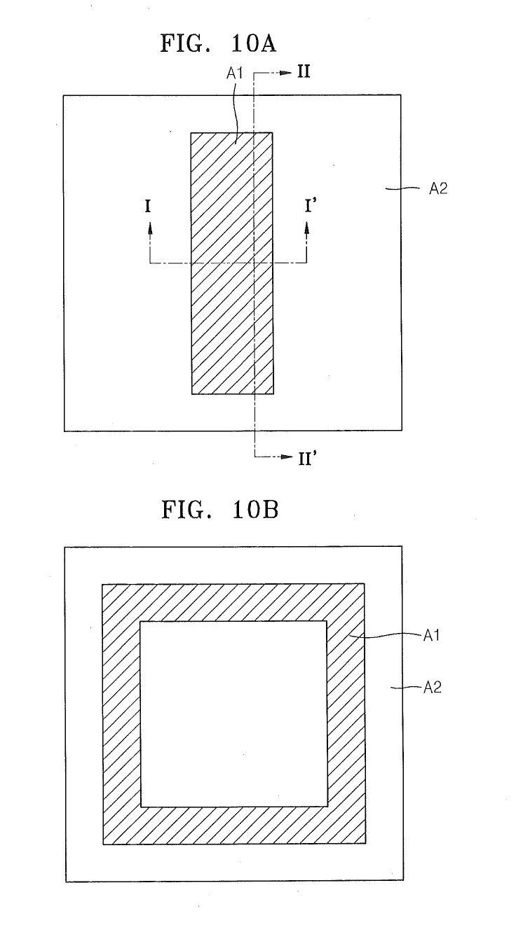

In relation to the semiconductor device 100, a recess Re1 having a predetermined depth may be formed in the back side Bs of the substrate 110, and a region having the recess Re1 may be defined as a recess region A1. As will be described later, the recess region A1, as a region where a plurality of TSVs 130 are disposed, may be the same region as the TSV arrangement region A1 shown in FIGS. 10A to 10E. The recess Re1 may expose the uppermost layer of the interlayer insulating layer part 150, i.e., a first interlayer insulating layer 151, and may have a depth corresponding to the height of the TSV 130. For example, the depth D1 of the recess Re1 may be less than about 50 μam. In accordance with various embodiments, the depth of the recess Re1 is not limited to the above value.

Here, the depth D1 of the recess Re1 may define the length from the back side Bs of the substrate 110 to the vertically-burrowed bottom surface. As shown in FIG. 1, the bottom surface of the recess Re1 is almost flush with the front side Fs of the substrate 110. This is only valid only at a portion adjacent to a recess region and, thus, the bottom surface of the recess Re1 may be different from the front side Fs of the substrate at other portions.

The insulating layer 120 may completely fill the recess Re1, and may cover the back side Bs of the substrate 110 of a region A2 other than the recess region A1. Hereinafter, for convenience of description, the region other than the recess region A1 is referred to as a non-recess region A2. The insulating layer 120 may include a first portion 120A1 corresponding to the recess region A1 and a second portion 120A2 corresponding to the non-recess region A1 The top surfaces of the first portion 120A1 and the second portion 120A2 of the insulating layer 120 may form the same plane. Accordingly, the thickness of the insulating layer 120 may be greater than the depth D1 of the recess region A1 in the first portion 120A1. Hereinafter, the top surface may define the side at the top facing the same direction as the back side Bs, and the bottom surface may define the side at the bottom facing the same direction as the top surface Fs of the substrate 110.

The insulating layer 120 may include an oxide layer or a nitride layer. For example, the insulating layer 120 may include a silicon oxide (SiO2) layer or a silicon nitride (SiNx) layer. In this embodiment, the insulating layer 120 may include a silicon oxide layer. The insulating layer 120 surrounds the lateral sides of the TSVs 130 to electrically insulate them from one other or from the substrate 110.

The TSV 130 may be formed in the recess region A1, i.e., the TSV arrangement region (refer to A1 of FIGS. 10A to 10E), and may penetrate the insulating layer 120. In relation to the semiconductor device 100, the TSV 130 may penetrate the insulating layer 120 and a portion of the interlayer insulating layer part 150, and the bottom surface of the TSV 130 may contact the wiring part 140, for example, a first wiring layer 142. Accordingly, the TSV 130 may be electrically connected to the first wiring layer 142. Moreover, the top surface of the TSV 130 is exposed through the top surface of the insulating layer 120, and a bump 132 may be disposed on the top surface of the TSV 130.

In this embodiment, the TSV 130 may be formed with a via-last structure. For reference, the TSV 130 may be classified into via-first, via-middle, and via-last. The via-first refers to a structure in which a TSV is formed before an integrated circuit layer is formed, the via-middle refers to a structure in which a TSV is formed after an integrated circuit layer is formed and before a wiring part is formed, and the via-last refers to a structure in which a TSV is formed after a wiring part is formed. In this embodiment, the TSV 130 may be formed with a via-last structure that is formed after all wiring parts are formed.

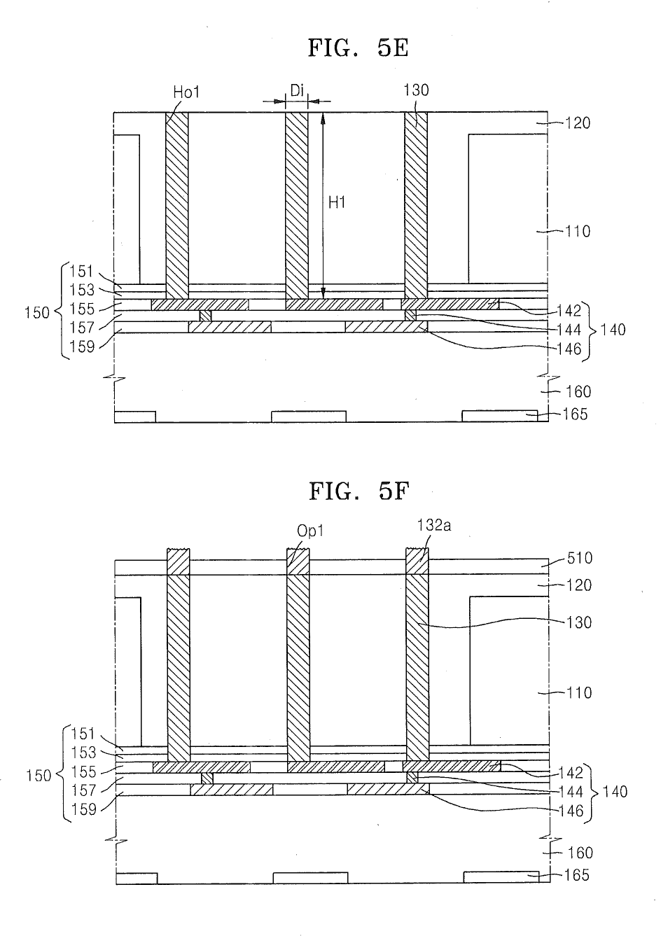

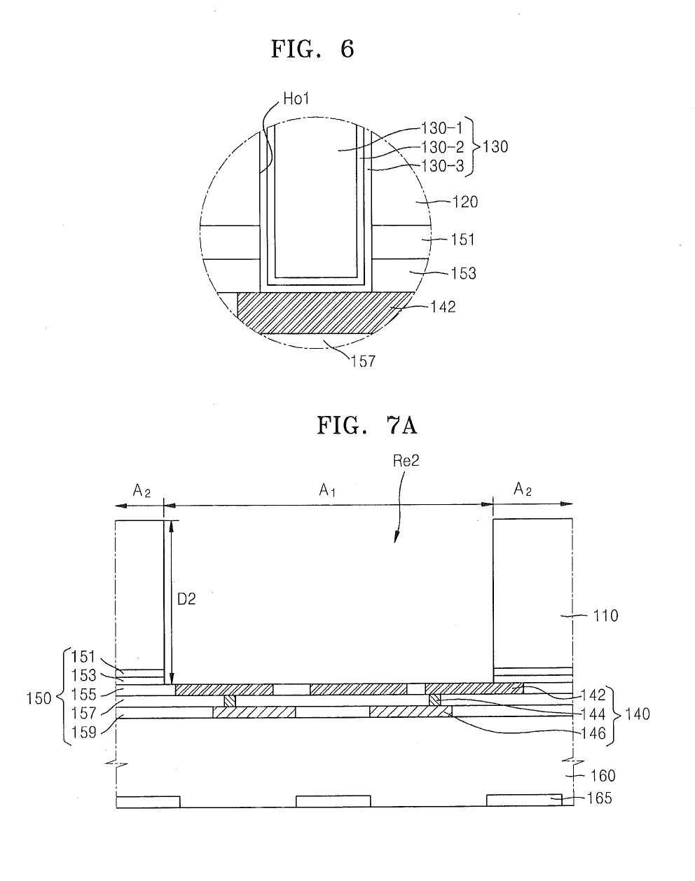

However, since the TSV of this embodiment is formed at the back side Bs of a substrate, it may be connected to the lowermost wiring layer of a wiring part, unlike a general via-last structure. This will be described later with reference to FIGS. 5A to 5F. Additionally, the structure or material of the TSV 130 will be described in more detail with reference to FIG. 6.

The wiring part 140 may include at least one wiring layer. For example, the wiring part 140 may include a first wiring layer 142, a vertical contact 144, and a second wiring layer 146. In this embodiment, although the wiring part 140 includes two wiring layers, it is apparent that the wiring part 140 may include one wiring layer or more than three wiring layers. When the wiring part 140 includes more than three wiring layers, wiring layers may be formed in the lower layer 160. As mentioned above, the lowermost first wiring layer 146 of the wiring part 140 may be electrically connected to the TSV 130.

Additionally, each wiring layer of the wiring part 140 may be electrically connected to an integrated circuit layer (not shown) on the top. For reference, the integrated circuit layer may be formed on the front side Fs of the substrate 110 or in the substrate 110, and may include a plurality of circuit devices. According to a function of an integrated circuit layer, a chip may be divided into a memory device or a logic device. For example, the memory device may include DRAM, SRAM, flash memory, EEPROM, PRAM, MRAM, or RRAM.

The interlayer insulating layer part 150 may include a plurality of interlayer insulating layers 151, 153, 155, 157, and 159. The interlayer insulating layers 151, 153, 155, 157, and 159 may serve to separate the wiring layers of the wiring part 140 from one other. Accordingly, a multilayer may be provided depending on the wiring layers of the wiring part 140. The interlayer insulating layer part 150 may be formed with a layer stacked structure including at least one of an oxide layer, a nitride layer, a low dielectric layer, and a high dielectric layer. In this embodiment, there are first and second interlayer insulating layers 151 and 153 on the first wiring layer 142, but in other embodiments, only one interlayer insulating layer or more than three interlayer insulating layers may be provided.

The lower layer 160 may serve to protect the bottom surface of the semiconductor device 100. According to the concept of this embodiment, the lower layer 160 includes the wiring part 140 and a portion of the interlayer insulating layer part 150. Accordingly, only a portion of the lowermost part of the lower layer 160 may be a passivation layer (not shown) protecting the top surface of a chip. The passivation layer may include an oxide layer or a nitride layer, and or may include a double layer of an oxide layer and a nitride layer. Additionally, the passivation layer in the lower layer 160 may include an oxide layer, for example, a silicon oxide (SiO2) layer, through an HDP-CVD process. An electrode pad 165 may be formed by penetrating the passivation layer. The electrode pad 165 may be electrically connected to a wiring layer in the lower layer 160.

In relation to the semiconductor device 100 of this embodiment, the recess region A1 is formed in a predetermined portion of the substrate 100 and is filled with the insulating layer 120, and then the TSV 130 penetrates the insulating layer 120. Therefore, the insulating layer 120 surrounding the TSV 130 may be formed thick, and accordingly, the cap and reliability of the semiconductor device 100 may be improved. Furthermore, the insulating layer 120 covers the back side of the substrate 110 in the non-recess region A2 other than the recess region A1 to serve as a protective layer, so that there is no need to form an additional protective layer on the back side Bs of the substrate 110.

For reference, when a general TSV is formed, a through hole is formed; an insulating layer is formed in the through hole; and then, the through hole is filled with copper. At this point, the insulating layer is generally deposited through a CVD process, and to improve cap and improve reliability, it is better to increase an overall thickness. As the aspect ratio of a through hole in recent and next generation devices is increased, step-coverage improvement may be required. Additionally, to reduce the size of a through hole, increase the aspect ratio of a through hole, and to improve the cap and improve reliability, the thickness of an insulating layer may need to be increased. As mentioned above, according to the semiconductor device of this embodiment, because an insulating layer is formed very thick, the above conditions may be satisfied, and also, the insulating layer may be easily formed through processes of FIGS. 5A to 5F.

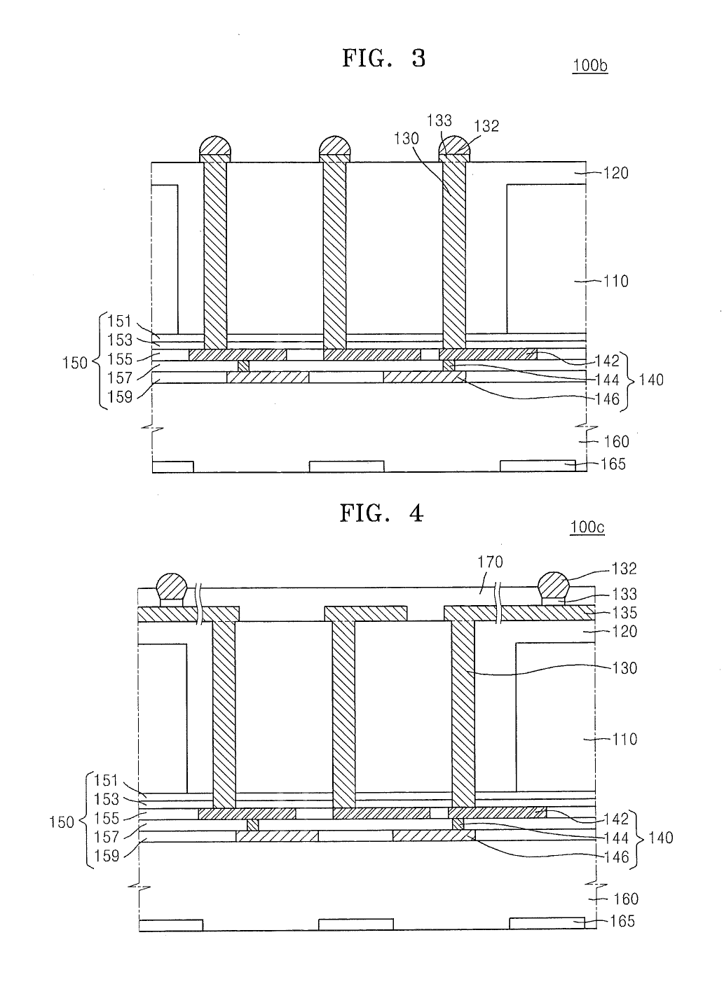

Referring to FIG. 2, although the semiconductor device 100a of this embodiment is similar to the semiconductor device 100 of FIG. 1, there are differences in the structure of the recess region A1 and the structure of the insulating layer 120 according thereto. That is, a recess Re2 is formed to expose the first wiring layer 142, and accordingly, there may be no first and second interlayer insulating layers 151 and 153 in the recess Re2. Furthermore, because there are no first and second interlayer insulating layers 151 and 153 in the recess Re2, the bottom surface of the insulating layer 120 may directly contact the first wiring layer 142 and the third interlayer insulating layer 155.

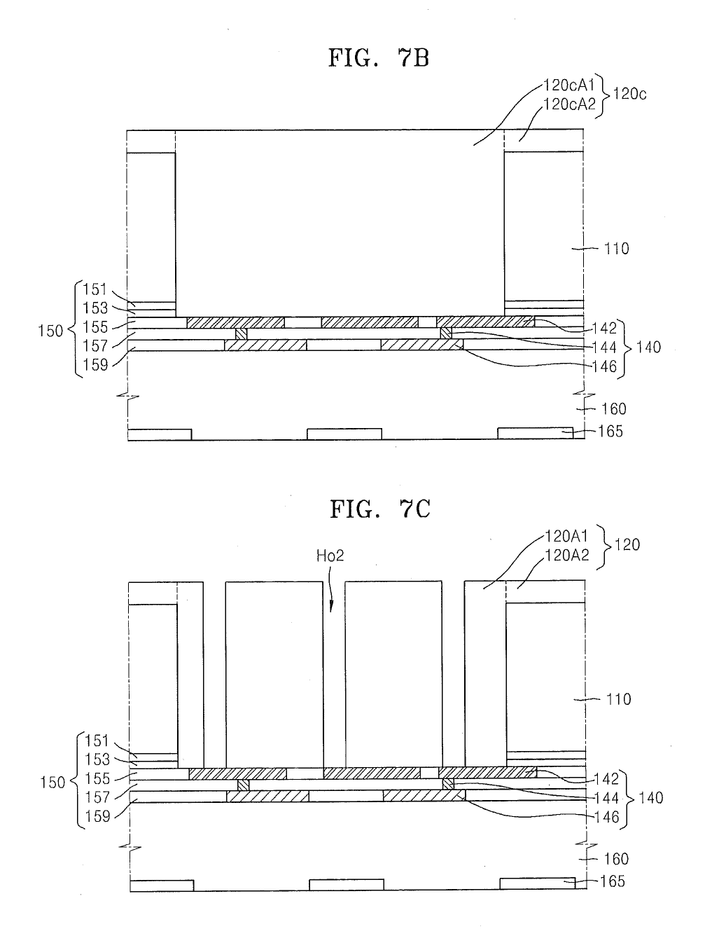

The structure of the semiconductor device 100a may be implemented by etching the substrate to expose the first wiring layer 142, unlike in the semiconductor device 100 of FIG. 1 in which the recess region A1 is formed in the substrate. Accordingly, the depth D2 of the recess Re2 may be greater than the depth D1 of the recess Re1 of the semiconductor device 100 of FIG. 1. This will be described in more detail with reference to FIG. 7A.

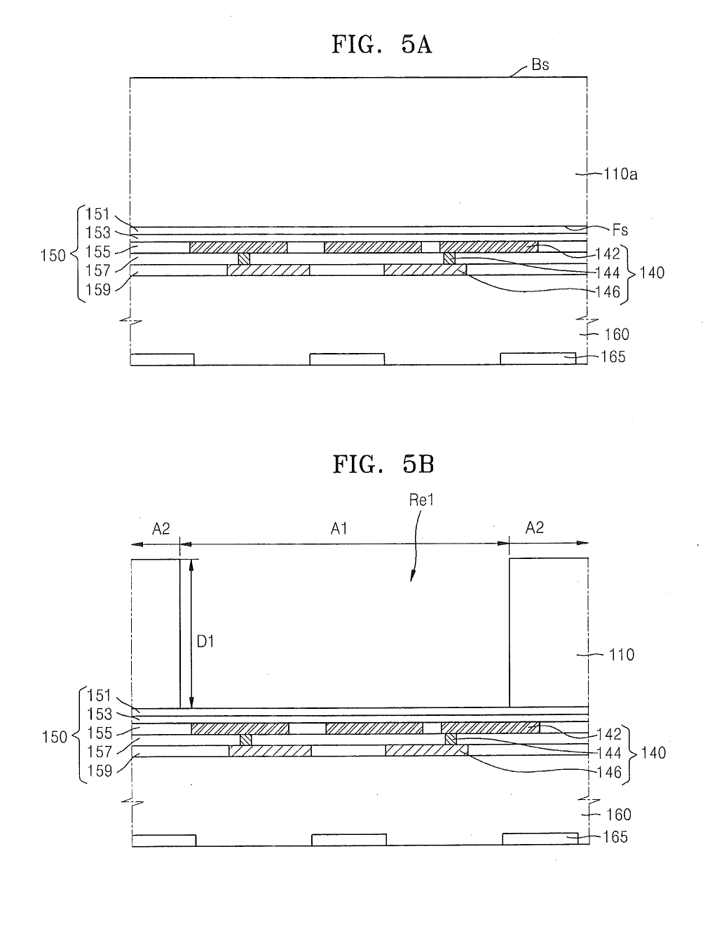

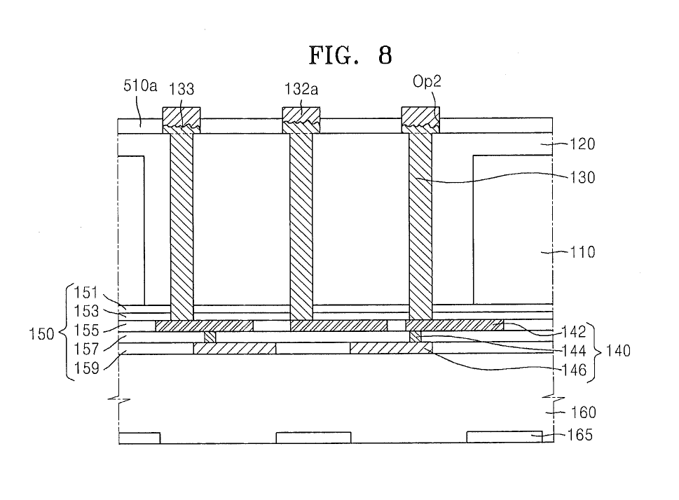

Referring to FIG. 3, although the semiconductor device 100b of this embodiment is similar to that 100 of FIG. 1, there are differences in that an upper pad 133 is formed on the top surface of the TSV 130 and a bump 132 is disposed on the upper pad 133. That is, the upper pad 133 is formed on the top surface of the TSV 130, and the upper pad 133 may have a larger area than the top surface of the TSV 130. The upper pad 133 may be formed of the same or different material than the TSV 130, or may be formed using the structure of a PR pattern 510a as shown in FIG. 8. The upper pad 133 and the bump 132 thereon will be described with reference to FIG. 8.

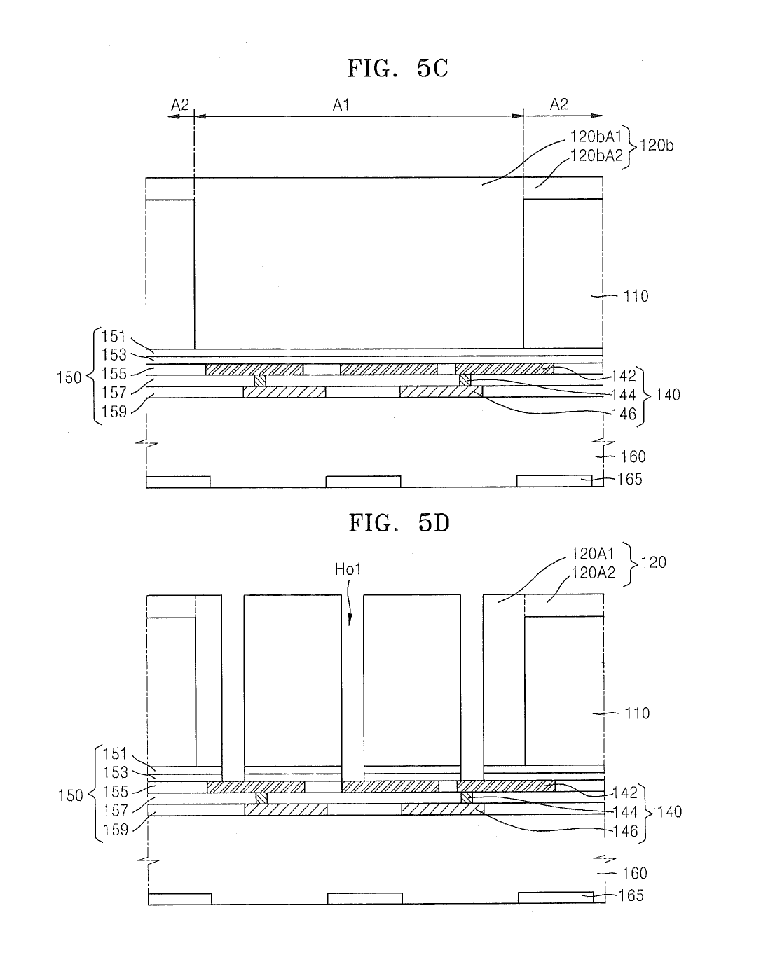

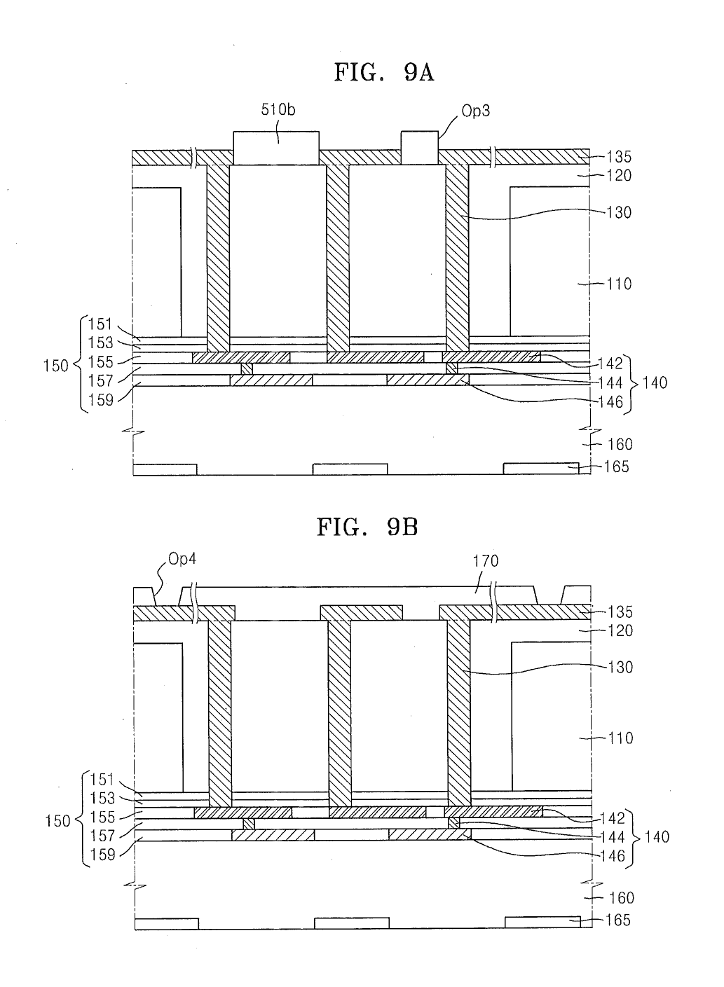

Referring to FIG. 4, the semiconductor device 100c may include a rewiring 135 on the insulating layer 120 and a resist layer 170 covering the rewiring 135. The rewiring 135 may contact the top surface of the TSV 130 and may extend from the top surface of the TSV 130 to the non-recess region A2. The upper pad 133 and the bump 132 may be disposed at the portion of the rewiring 135 in the non-recess region A2. The rewiring 135 may be formed using the PR pattern 510b of FIG. 9A. The rewiring 135 and the resist layer 170 will be described in more detail with reference to FIGS. 9A and 9B.

FIGS. 5A and 5F are cross-sectional views illustrating a method of manufacturing a semiconductor device including the TSV of FIG. 1 according to some embodiments of the inventive subject matter.

Referring to FIG. 5A, a wiring part 140, an interlayer insulating layer part 150, a lower layer 160, and an electrode pad 165 are formed on the front side Fs of the substrate 110a. Also, although not shown in the drawing, an integrated circuit layer may be formed in or on the substrate 110a before the wiring part 140 and the interlayer insulating layer part 150 are formed. In FIG. 5A, the top surface of the substrate 110a is the back side Bs and its bottom surface is the front side Fs. That is, the front side Fs of the substrate 110a may be an active surface where an integrated circuit layer and the wiring part 140 are formed.

Referring to FIG. 5B, the recess Re1 exposing the first interlayer insulating layer 151 is formed by etching the substrate 110 from the back side Bs of the substrate 110, so that the recess region A1 is formed. The recess region A1 may be a TSV arrangement region where a TSV is disposed. A region other than the recess region A1 may be a non-recess region A2. The recess region A1 may be formed through wet etching or dry etching. In this embodiment, the recess region A1 may be formed through dry etching.

Moreover, although the recess Re1 is formed to expose the first interlayer insulating layer 151, it may be formed to expose the second interlayer insulating layer 153, or may be formed to expose the first wiring layer 142 and the third interlayer insulating layer 155 by completely removing the first interlayer insulating layer 151 and the second interlayer insulating layer 153. The first interlayer insulating layer 151 may be a silicon oxide layer or a silicon nitride layer, and accordingly, may have an etch selectivity with respect to the substrate 110 formed of silicon. The first interlayer insulating layer 151 may serve as an etch stop layer.

The depth D1 of the recess Re1 may vary depending on the thickness of the substrate 110. That is, the substrate 110 becomes thinner as its back side is removed through a back-lap process after the integrated circuit layer, the wiring part 140, and the lower layer 160 are formed. After such a back-lap process, the substrate 110 may have a thickness of about 10 μm to about 100 μm, and because the recess Re1 is formed depending on the thickness of the substrate 110, the depth D1 of the recess Re1 may be in a range of about 1 μm to about 100 μm. The depth D1 of the recess Re1 in this embodiment may be in a range of about 1 μm to about 50 μm.

Referring to FIG. 5C, the insulating layer 120b covering the back side of the substrate 110 in the non-recess region A2 is formed by filling the recess region A1. The insulating layer 120b may include a silicon oxide layer or a silicon nitride layer. For example, in this embodiment, the insulating layer 120b may include a silicon oxide layer.

The insulating layer 120b may include a first portion 120bA1 corresponding to the recess region A1 and a second portion 120bA2 corresponding to the non-recess region A2. The top surface of first portion 120bA1 of the insulating layer 120b and the top surface of the second portion 120bA2 may form the same plane. A Chemical Mechanical Polishing (CMP) process may be performed on the insulating layer 120b to allow the top surface of the first portion 120bA1 and the top surface of the second portion 120bA2 of the insulating layer 120b to form the same plane.

The insulating layer 120b may be formed through spin coating, such as a spin on glass (SOG) coating. In general, when the recess region A1 is deep, the insulating layer 120b is formed through spin coating, and when the recess region A1 is relatively narrow and thin, the insulating layer 120b is formed through a CVD method. For example, if the depth of the recess region A1 is less than about 10 μm, the insulating layer 120b may be formed through a CVD method. Moreover, when the insulating layer 120b is formed through a CVD method, a CMP process may be performed to planarize the top surface thereof.

The second portion 120bA2 of the insulating layer 120b covering the back side Bs of the substrate 110 in the non-recess region A2 may serve as a protective layer for the substrate 110. In general, in order to protect the substrate 110 after a TSV process, a protective layer such as a passivation layer may be formed on the back side of the substrate 110. However, according to this embodiment, because the insulating layer 120b already covers the back side Bs of the substrate 110, there is no need to form an additional protective layer on the back side Bs of the substrate 110 later.

Referring to FIG. 5D, a plurality of through holes Ho1 are formed to penetrate the insulating layer 120 and first and second interlayer insulating layers 151 and 153 of the recess region A1. The through hole Ho1 may expose the first wiring layer 142. The through hole Ho1 may be formed in the recess region A1 in correspondence to the number and positions of TSVs to be formed.

Moreover, the through hole Ho1 may have a relatively large aspect ratio. For example, the through hole Ho 1 may have an aspect ratio of more than 10. In more detail, the through hole Ho1 may be formed with a cylindrical form, and its diameter (refer to Di of FIG. 5E) may be in a range of about 5 μm to about 10 μm, and its depth (refer to H1 of FIG. 5E) may be in a range of about 50 μm to about 60 μm. Additionally, its diameter Di may be less than about 1 μm, and its depth H1 may be equal to or less than about 10 μm. Of course, the form of the through hole Ho1 is not limited to a cylindrical form, and also its size is not limited to the above values.

Referring to FIG. 5E, the through hole Ho1 is filled with a metallic material such as Cu to form the TSV 130. In more detail, a barrier layer (not shown) is first formed in the through hole Ho1, and a seed metal is deposited on the barrier layer. Then, Cu fills in the through hole Ho1 by using the seed metal as a seed through a plating method so as to complete the TSV 130.

The top surface of the TSV 130 and the top surface of the insulating layer 120 may form the same plane. To allow the top surface of the TSV 130 to match the top surface of the insulating layer 120, the through hole Ho 1 may be filled with Cu and then, a CMP process may be performed.

The TSV 130 may have the same structure as the through hole Ho1. For example, the through hole Ho1 is formed with a cylindrical form, the structure of the TSV 130 may have a cylindrical form. Additionally, the size of the TSV 30 may determined depending on the size of the through holes Ho1. For example, the diameter Di of the TSV 130 may be in a range of about 5 μm to about 10 μm, and its height H1 may be in a range of about 50 μm to about 60 μm. Additionally, its diameter Di may be less than about 1 μm and its depth H1 may be equal to or less than about 10 μm. Like the through hole Ho1 mentioned above, the form of the TSV 130 is not limited to a cylindrical form. For example, the TSV 130 may have various forms, such as a polygonal pillar or an oval pillar.

Referring to FIG. 5F, a photo resist (PR) pattern 510 is formed on the insulating layer 120. The PR pattern 510 may have an opening Op1 that opens the top surface of the TSV 130. A material 132a for forming a bump may fill in the opening Op1. The material 132a for forming a bump may include Sn. In some cases, the material 132a for forming a bump may include Sn, Pd, Ni, Ag, Pb, or combinations thereof.

When a reflow process is performed on the material 132a for forming a bump, a hemispherical bump 132 may be formed as shown in FIG. 1. The PR pattern 510 may be removed before the reflow process. In some cases, without forming the PR pattern 510, the material 132a for forming a bump is disposed on the TSV 130, and then, a reflow process is performed on the material 132a for forming a bump so as to form the bump 132.

FIG. 6 is a detailed cross-sectional view illustrating the structure of a TSV in a semiconductor device including the TSV according to some embodiments of the inventive subject matter. An enlarged portion A of FIG. 1 is shown in FIG. 6.

Referring to FIG. 6, the TSV 130 may include a center metallic layer 130-1, a seed metallic layer 130-2, and a barrier layer 130-3.

The center metallic layer 130-1 and the seed metallic layer 130-2 may be formed of the same or different material, The center metallic layer 130-1 and the seed metallic layer 130-2 may include at least one of Al, Au, Be, Bi, Co, Cu, Hf, In, Mn, Mo, Ni, Pb, Pd, Pt, Rh, Re, Ru, Ta, Te, Ti, W, Zn, and Zr. In this embodiment, the center metallic layer 130-1 and the seed metallic layer 130-2 may be formed of Cu. Moreover, the barrier layer 130-3 may have a layer stacked structure including at least one of Ti, Ta, TiN, and TaN. However, the center metallic layer 130-1, the seed metallic layer 130-2, and the barrier layer 130-3 are not limited to the above materials. Moreover, in some cases, the barrier layer 130-3 may be omitted.

As description is made with reference to FIG. 5E, the barrier layer 130-3 is first formed in the through hole Ho1, and then, the seed metallic layer 130-2 is formed on the barrier layer 130-3. Then, the center metallic layer 130-1 is formed by using the seed metallic layer 130-2 as a seed through a plating method. The TSV 130 may electrically contact the first wiring layer 142 as shown in the drawing.

FIGS. 7A-7C are cross-sectional views illustrating a method of manufacturing a semiconductor device including the TSV of FIG. 2 according to some embodiments of the inventive subject matter. FIG. 7A corresponds to FIG. 5B, FIG. 7B corresponds to FIG. 5C, and FIG. 7C corresponds to FIG. 5D.

Referring to FIG. 7A, according to this embodiment, the recess Re2 of the recess region A1 may expose the first wiring layer 142 and the third interlayer insulating layer 155. The recess region A1 may be formed through wet etching or dry etching. Moreover, the third interlayer insulating layer 155 may include a silicon oxide layer or a silicon nitride layer. The third interlayer insulating layer 155 may have an etch selectivity with respect to the substrate 110 and the first and second interlayer insulating layer 151 and 153. Accordingly, the third interlayer insulating layer 155 may serve an etch stop layer.

The depth D2 of the recess Re2 may vary depending on the thickness of the substrate 110. However, because the first and second interlayer insulating layers 151 and 153 are etched, the depth D2 of the recess Re2 may be greater than the depth D1 of the recess Re1 of FIG. 5B. For example, the depth D2 of the recess Re2 may be in a range of about 10 μm to about 50 μm.

Referring to FIG. 7B, the insulating layer 120b filling in the recess region A1 and covering the back side of the substrate 110 in the non-recess region A2 is formed. The insulating layer 120c may include a silicon oxide layer or a silicon nitride layer.

The insulating layer 120c may include a first portion 120cA1 filling in the recess region A1 and a second portion 120cA2 on the non-recess region A2. The top surface of the first portion 120cA1 and the top surface of the second portion 120cA2 of the insulating layer 120b may form one plane. The insulating layer 120c may be also formed through spin coating or CVD.

In this embodiment, the second portion 120cA2 of the insulating layer 120c covering the back side of the substrate 110 in the non-recess region A2 may serve as a protective layer for the substrate 110. Accordingly, there is no need to form an additional protective layer on the back side of the substrate 110 later.

Referring to FIG. 7C, a plurality of through holes Hot are formed to penetrate the insulating layer 120 of the recess region A1. The through hole Ho2 may expose the first wiring layer 142. The through hole Ho2 may be formed in the recess region A1 in correspondence to the number and positions of TSVs to be formed. Because there are no first and second interlayer insulating layers 151 and 153 in the recess region A1, the through hole Ho2 may expose the first wiring layer 142 by penetrating only the insulating layer 120.

The through hole Ho2 in this embodiment may have a relatively large aspect ratio, for example, more than 10. In more detail, the through hole Ho2 is formed with a cylindrical form. The diameter Di of the through hole Ho2 may be in a range of about 5 μm to about 10 μm, and its depth may be in a range of about 50 μm to about 60 μm. Additionally, its diameter Di may be less than about 1 μm, and its depth H1 may be equal to or less than about 10 μm.

The next processes are identical to those of FIGS. 5E and 5F. For example, a TSV is formed by filling a metallic material in the through hole Ho2, and then, the semiconductor device 100a of FIG. 2 is completed by forming a bump on the TSV.

FIG. 8 is a cross-sectional view illustrating a method of manufacturing a semiconductor device including the TSV of FIG. 3 according to some embodiments of the inventive subject matter. FIG. 8 may correspond to FIG. 5F.

Referring to FIG. 8, after the TSV 130 is formed, a PR pattern 510a is formed on the top surfaces of the insulating layer 120 and the TSV 130. Unlike FIG. 5F, the opening Op2 of the PR pattern 510a may expose the top surface of the TSV 130 and a portion of the insulating layer 120 around the TSV

After the PR pattern 510a is formed, the upper pad 133 is formed on the top surface of the TSV 130. The upper pad 133 may be formed of a metal, such as A1 or Cu, and with a thickness of about 3 μm to about 10 μm. In this embodiment, the upper pad 133 and the TSV 130 may be formed of the same metal, i.e., Cu. The upper pad 133 may be formed through plating.

After the upper pad 133 is formed, the material 132a for forming a bump is disposed on the upper pad 133, and the bump 132 of FIG. 3 is formed through a reflow process, so that the semiconductor device 100b having the structure of FIG. 3 is completed. As mentioned above, the material 132a for forming a bump may include Sn, and in some cases, the material 132a for forming a bump may include Sn, Pd, Ni, Ag, Pb, or combinations thereof.

FIGS. 9A and 9B are cross-sectional views illustrating a method of manufacturing a semiconductor device including the TSV of FIG. 4 according to some embodiments of the inventive subject matter.

Referring to FIG. 9A, after the TSV 130 is formed, as shown in FIG. 5E, a PR pattern 510b is formed on the top surfaces of the insulating layer 120 and the TSV 130. The PR pattern 510b may have an opening part Op3 that opens the top surface of the TSV 130 and a predetermined portion of the insulating layer 120. In more detail, the opening Op3 may have a structure extending from the top surface of the TSV 130 to a predetermined portion on the insulating layer 120 along one direction.

In this structure, a seed metal is deposited in the opening Op3 and a metallic layer is formed by using the seed metal as a seed, so that a rewiring 135 is formed. The rewiring 135 may be formed of Cu, for example. According to the structure of the opening Op3, the rewiring 135 may have a structure that contacts the top surface of the TSV 130 and extends from the top surface of the TSV 130 to a predetermined portion on the insulating layer 120 along one direction. After the rewiring 135 is formed, the PR pattern 510b may be removed.

Referring to FIG. 9B, after the PR pattern 510b is removed, a resist layer 170 covering the rewiring 135 and the exposed insulating layer 120 is formed. The resist layer 170 may have an opening Op4 that exposes a predetermined portion of the rewiring 135. Then, by forming the upper pad 133 of FIG. 4 and the bump 132 of FIG. 4 on the opening Op4, the semiconductor device 100c of FIG. 4 may be completed.

In this embodiment, the resist layer 170 covering the rewiring 135 is formed, but this embodiment is not limited thereto. For example, instead of the resist layer 170, an oxide layer, a nitride layer or a Photosensitive Polyimide (PSPI) layer (including a polymer based material) may be formed to protect the rewiring 135.

The semiconductor device of this embodiment has a structure that is implemented when the upper pad and bump 133 and 132 are not directly formed on the top surface of the TSV 130, and are formed on another portion, as shown in FIG. 4. For example, when the upper pad and bump 133 and 132 are not formed in the recess region A1 and are formed in the non-recess region A2, the TSV 130 is electrically connected to the upper pad 133 through the rewiring 135.

FIGS. 10A to 10E are plan views of a region having a TSV according to embodiments of the inventive subject matter.

Referring to FIGS. 10A to 10E, a region having a TSV in a semiconductor device, i.e., a TSV arrangement region A1, may have various structures.

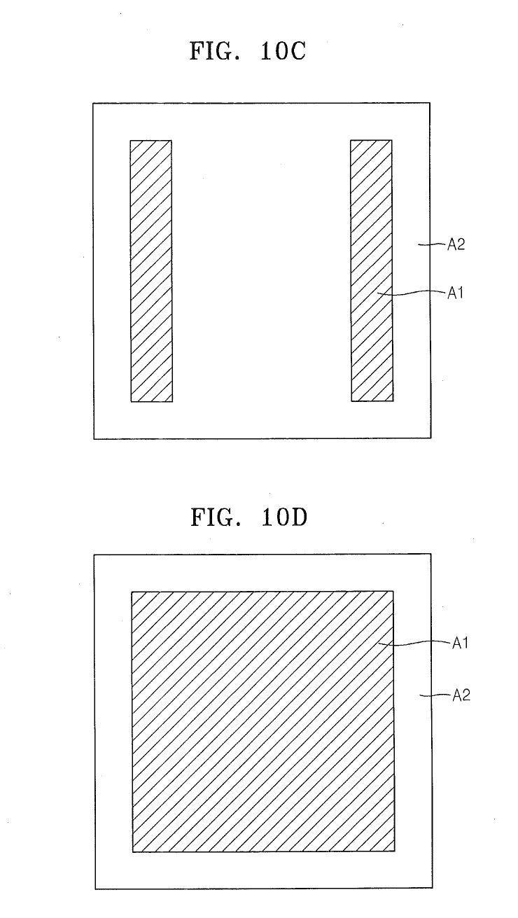

In more detail, as shown in FIG. 10A, the TSV arrangement region A1 may have an elongated rectangular form at the center of the semiconductor device. Here, A2 may refer to a TSV non-arrangement region. The TSV arrangement region A1 of FIG. 10A may correspond to the recess region A1 of FIGS. 1 to 4. Accordingly, the section taken along line I-I′ of FIG. 10A may correspond to FIGS. 1 to 4. Additionally, the section taken along line II-II′ of FIG. 10A may correspond to the first chip 100 of FIGS. 11 to 13.

The TSV arrangement region A1 may have a rectangular ring form along the outline of the semiconductor device, as shown in FIG. 10B. Additionally, the TSV arrangement region A1 may have two rectangular structures that extend to be elongated along the both sides of the semiconductor device, as shown in FIG. 10C. In some cases, the TSV arrangement region A1 may be formed over almost the entire semiconductor device, as shown in FIG. 10D. Additionally, the TSV arrangement region A1 may be formed at the center portion and may be formed with a rectangular ring form surrounding the center portion, as shown in FIG. 10E. For reference, the structure of FIG. 10A is mainly used for a memory device such as DRAM, and the structure of FIG. 10D or 10E is used for a logic device. Additionally, the structure of FIG. 10B or 10C may be generally used for a memory device, a logic device, an interposer, and/or a support substrate.

FIGS. 11 to 13 are cross-sectional views of a semiconductor package according to embodiments of the inventive subject matter.

Referring to FIG. 11, the semiconductor package 1000 may include a first chip 100, a second chip 200, an underfill 310, and a sealing material 300.

The first chip 100 may have the same structure as the semiconductor device 100b of FIG. 3. That is, the chip 100 may include an insulating layer 120, a TSV 130, a wiring part 140, an interlayer insulating layer part 150, and a lower layer 160. An integrated circuit layer (not shown) may be formed in or on the substrate 110. Because each part was described with reference to FIG. 1, overlapping description is omitted.

Moreover, the wiring part 140, the interlayer insulating layer part 150, and the lower layer 160 are shown as one integration layer 140, 150, and 160 to simplify the drawing of FIG. 11. Additionally, although the TSV 130 is connected to a first wiring layer (not shown) of the wiring part 140 by penetrating the insulating layer 120, the TSV 130 contacting the integration layer 140, 150, and 160 is simply shown in the drawing. As mentioned above, according to this embodiment, the TSV 130 may be formed with a via-last structure that is formed after the wiring part 140 is completed. Moreover, the upper pad 133 and the bump 132 may be disposed on the top surface of the TSV 130. Additionally, as shown in FIG. 11, an external connection member 180, for example, a solder ball or a bump, is disposed on the electrode pad 165 at the bottom.

The second chip 200 may include a substrate 210, a wiring part 240, an interlayer insulating layer part 250, and a lower layer 260. An integrated circuit layer (not shown) may be formed in or on the substrate 210. A TSV cannot be formed in the second chip 200. Accordingly, a recess region may not be formed in the substrate 210, and also, an insulating layer filling in the recess region may not be formed. Moreover, in relation to the second chip 200, the wiring part 240, the interlayer insulating layer part 250, and the lower layer 260 are shown as one integration layer 240, 250, and 260 to simplify the drawing. An electrode pad 265 may be disposed at the bottom of the integration layer 240, 250, and 260.

The underfill 310 may fill in a connection portion of the first chip 100 and the second chip 200, that is, a portion where the bump 132 of the first chip 100 is connected to the electrode pad 265 of the second chip 200. The underfill 310 may be formed of an underfill resin such as epoxy resin, and may include a silica filler or flux. The underfill 310 may be formed of the same or different material than the sealing material 300 at the outline.

Moreover, as shown in the drawing, the underfill 310 is formed to surround the connection portion of the first chip 100 and the second chip 200 and also is formed to extend from the connection portion to surround the first chip 100. Accordingly, the underfill 310 may seal the lateral side of the first chip 100. Additionally, the bottom surface of the underfill 310 and the bottom surface of the sealing material 300 at the outline may form the same horizontal plane.

In FIG. 11, the underfill 310 may have a form widening in the bottom direction, but is not limited thereto. That is, the underfill 310 may have various structures. For example, the underfill 310 may not surround the lateral side of the first chip 100 and may be formed only between the first chip 100 and the second chip 200. In such a structure, the top and bottom of the underfill 310 may have the same area.

The sealing material 300 seals the first chip 100 and the second chip 200. The sealing material 300 may be formed of a polymer such as resin. For example, the sealing material 300 may be formed of an Epoxy Molding Compound (EMC). Due to the underfill 310, the sealing material 300 may seal the lateral sides of the second chip 200 and the underfill 310. Additionally, when the underfill 310 is formed only between the first and second chips 100 and 200, the sealing material 300 may also surround the lateral side of the first chip 100.

The top surface of the sealing material 300 and the top surface of the second chip 200 may form the same horizontal plane. Accordingly, the top surface of the second chip 200 may be exposed to the outside. As mentioned above, the bottom surface of the underfill 310 and the bottom surface of the sealing material 300 may form the same horizontal plane. Additionally, the bottom surfaces of the underfill 310 and the sealing material 300 and the bottom surface of the lower layer 160 in the first chip 100 may form the same horizontal plane.

As described above, in relation to the semiconductor package of this embodiment, a recess region of the substrate 110 is filled with the insulating layer 120, and then the TSV 130 is formed by penetrating the insulating layer 120 in the first chip 100. Therefore, the insulating layer 120 surrounding the TSV 130 may be formed thick, and accordingly, the cap and the reliability of the semiconductor package 1000 may be improved. Furthermore, the insulating layer 120 covers the back side of the substrate 110 in the non-recess region A2 other than the recess region A1 to serve as a protective layer, so that there is no need to form an additional protective layer on the back side Bs of the substrate 110. As a result, manufacturing processes for the first chip 100 may be simplified.

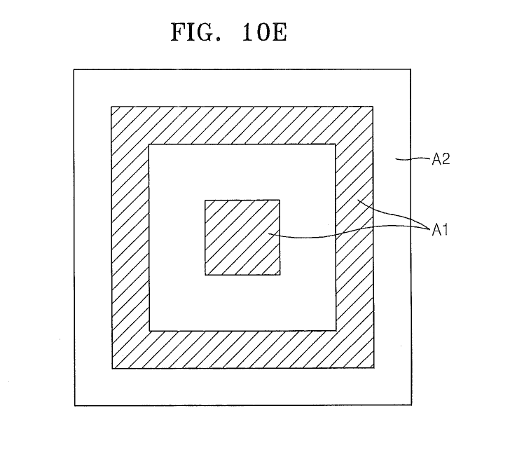

Referring to FIG. 12, the semiconductor package 1000a may include N chips 100, 200, . . . , Nth_chip, two or more of an adhesive member 320, and a sealing material 300. Here, N may be an integer of more than 3.

A TSV and an upper pad for electrical connection between chips may be formed in each chip other than the uppermost chip Nth_chip among the N chips 100, 200, . . . , Nth_chip. That is, each chip except for the uppermost chip Nth_chip may have the same structure as the semiconductor device 100b of FIG. 3. Moreover, because another chip is not stacked on the uppermost chip Nth_chip, a TSV and an upper pad may not be formed on the uppermost chip Nth_chip.

The adhesive member 320 fills in between chips and may be formed of a non-conductive film (NFC). However, the adhesive member 320 is not limited to the NCF. For example, the adhesive member 320 may be formed of an Anisotropic Conductive Film (ACF), a UV film, an instance adhesive, a thermosetting adhesive, a laser curable adhesive, an ultrasound curable adhesive, and a Non-Conductive Paste (NCP). Additionally, instead of the adhesives, an underfill may be used.

Moreover, only the bump 232 and the adhesive member 320 are disposed on the top surface of the second chip 200, and this is for describing the drawing of a chip unit. In reality, the bump 232 of the second chip 200 and the electrode pad of the chip thereabove may be connected to each other at the portion of the adhesive member 320. The adhesive member 320 may not be formed on the top surface of the uppermost chip Nth_chip.

The sealing material 300 may be formed to surround the lateral side of each of the N chips 100, 200, . . . , Nth_chip. Additionally, the top surface of the sealing material 300 and the top surface of the uppermost chip Nth_chip may form the same horizontal plane.

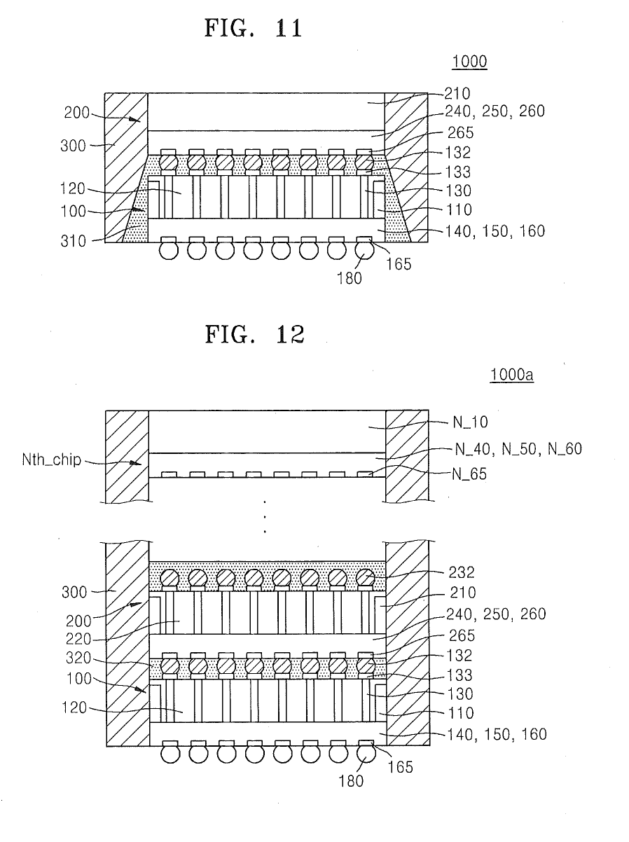

Referring to FIG. 13, the semiconductor package 10000 of this embodiment may include a main chip 2000 and an upper semiconductor package 1000.

The upper semiconductor package 1000 may be identical to the semiconductor package 1000 of FIG. 11. Accordingly, description for each component of the upper semiconductor package 1000 is omitted or only briefly made.

The main chip 2000 may have a larger size than the first and second chips 100 and 200 in the upper semiconductor package 1000. For example, the horizontal sectional size of the main chip 2000 may be identical to the entire horizontal sectional size of the upper semiconductor package 1000, that is, the horizontal sectional size including the sealing material 300. Moreover, the upper semiconductor package 1000 may be mounted on the main chip 2000 through the adhesive member 2400. Accordingly, the bottom surfaces of the sealing member 300 and the underfill 310 in the upper semiconductor package 1000 may be bonded to the outer border portion of the main chip 2000 through the adhesive member 2400.

The main chip 2000 may include a body layer 2100, a lower insulating layer 2200, a passivation layer 2300, a TSV 2500, an external connection member 2600, and an upper pad 2700. An integrated circuit layer (not shown) and a multilayer wiring pattern (not shown) may be included in the body layer 2100 and/or the lower insulating layer 2200, and such an integrated circuit layer and multilayer wiring pattern may be diversely formed depending on the types of a main chip. The main chip 2000 may be a logic chip, such as a central processing unit (CPU), a controller, or an application specific integrated circuit (ASIC).

In this embodiment, although the upper semiconductor package 1000 stacked on the main chip 2000 is shown, it may be directly mounted on a support substrate, such as a PCB or a package substrate.

Moreover, the number of the TSVs 2500 and the number of the upper pads 2700 corresponding thereto may be provided in correspondence to the number of the external connection members 180 of the first chip 100 in the upper semiconductor package 1000 stacked on the main chip 2000. In some cases, the number of the TSVs 2500 may be different from the number of the external connection members 180 of the first chip 100. For example, the number of the TSVs 2500, which is greater than the number of the external connection members 180 of the first chip 100, may be provided.

The external connection member 2600 formed at the bottom surface of the main chip 2000 may include a bump pad 2610 and a solder ball 2620, and the number of the external connection members 2600 may be less than the number of the TSVs 2500. Accordingly, in the case of the TSV 2500 to which no external connection member 2600 corresponds, the TSV 2500 may be incorporated into one external connection member 2600 and may be connected through an internal multilayer wiring pattern.

Moreover, the external connection member 2600 in the main chip 2000 may have a greater size than the external connection member 180 in the upper semiconductor package 1000. This is because there are limitations in densification due to a standardized wiring on a board substrate (not shown) where the main chip 2000 is mounted or the physical property of the board substrate (for example, a plastic board substrate) where the main chip 2000 is mounted. For this reason, all of the above TSVs 2500 may not respectively correspond to the external connection members 2600.

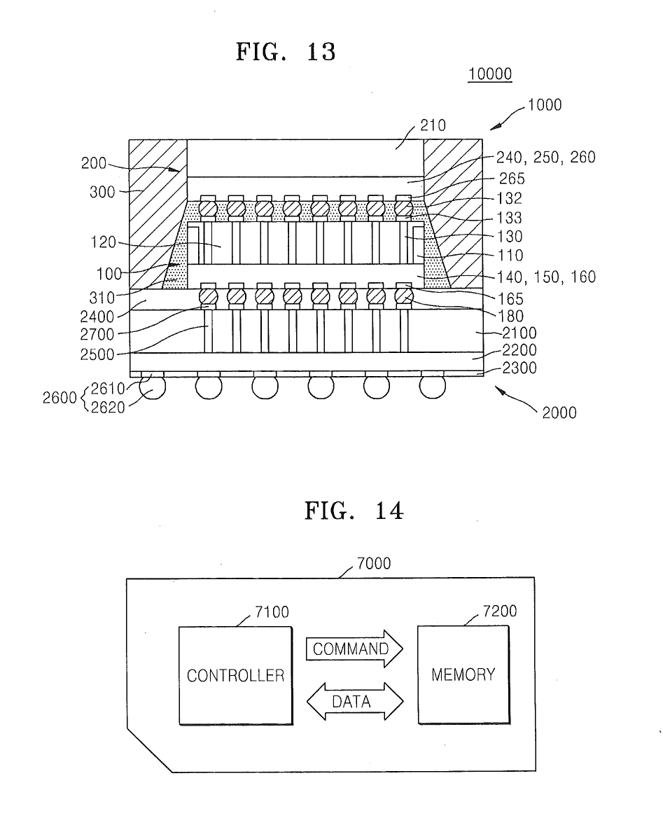

FIG. 14 is a block diagram illustrating a memory card including a semiconductor package according to some embodiments of the inventive subject matter.

Referring to FIG. 14, a controller 7100 and a memory 7200 are disposed to exchange electrical signals in the memory card 7000. For example, when the controller 7100 sends a command, the memory 7200 transmits data. The controller 7100 and/or the memory 7200 may include a semiconductor package according to one of the embodiments of the present invention. The memory 7200 may include a memory array (not shown) or a memory array bank (not shown).

The card 7000 may include various kinds of cards, such as a memory stick card, a smart media card (SM), a secure digital (SD), a mini secure digital card; mini (SD), or a multi media card (MMC), and may be used for a memory device.

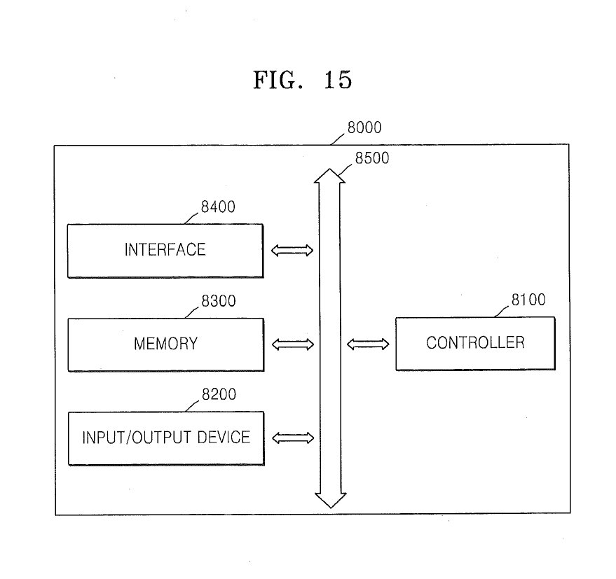

FIG. 15 is a block diagram illustrating an electronic system including a semiconductor package according to some embodiments of the inventive subject matter.

Referring to FIG. 15, the electronic system 8000 may include a controller 8100, an input/output device 8200, a memory 8300, and an interface 8400. The electronic system 8000 may be a mobile system, or a system for transmitting/receiving information. The mobile system may include a PDA, a portable computer, a web tablet, a wireless phone, a mobile phone, a digital music player, or a memory card.

The controller 8100 executes a program and controls the electronic system 8000. The controller 8100 may include a micro processor, a digital signal processor, a micro controller, or a device similar thereto. The input/output device 8200 may input or output data of the electronic system 8000.

The electronic system 8000 may be connected to an external device such as a personal computer or a network by using the input/output device 8200 so as to exchange data with the external device. The input/output device 8200 may include a keypad, a keyboard, or a display. The memory 8300 may store the code and/or data for operation of the controller 8100, and/or may store the data processed by the controller 8100. The controller 8100 and the memory 8300 may include a semiconductor package according to one of the embodiments of the present invention. The interface 8400 may be a data transmission path between the electronic system 8000 and another external device. The controller 8100, the input/output device 8200, the memory 8300, and the interface 8400 may communicate with each other via a bus 8500.

For example, the electronic system 8000 may be used for mobile phones, MP3 players, navigation systems, portable multimedia players (PMPs), solid state disks (SSDs), or household appliances.

In relation to a semiconductor device including a TSV and a semiconductor package including the semiconductor device according to the technical ideas of the inventive subject matter, a recess area is formed in a predetermined portion of a substrate and is filled with an insulating layer, and then a TSV penetrates the filled insulating layer. Therefore, the insulating layer surrounding the TSV may be formed thick, and accordingly, the cap and reliability of a semiconductor device may be improved.

Furthermore, the insulating layer covers the back side of the substrate in a non-recess area other than a recess area to serve as a protective layer, so that there is no need to form an additional protective layer on the back side of the substrate.

While the inventive concept has been particularly shown and described with reference to exemplary embodiments thereof, it will be understood that various changes in form and details may be made therein without departing from the spirit and scope of the following claims.

What is claimed is:

1. A semiconductor device comprising:
a substrate having a recess region in a predetermined portion of a back side of the substrate;
a wiring part disposed on a front side of the substrate and including at least one wiring layer;
an insulating layer disposed on the back side of the substrate and including a first portion filling in the recess region and a second portion covering the back side of the substrate of a non-recess region other than the recess region; and
a through silicon via (TSV) provided in plurality and penetrating the first portion to be electrically connected to the at least one wiring layer.

2. The semiconductor device of claim 1, wherein the wiring part comprises at least two wiring layers, and the TSV is connected to one of the wiring layers that is most adjacent to the insulating layer.

3. The semiconductor device of claim 1, wherein the semiconductor device has a rectangle portion that is horizontally shaped; and
a horizontal section of the recess region has one of a rectangular ring form surrounding an outer border portion of the rectangle portion, an elongated rectangular form extending from a center portion of the rectangle portion, two elongated rectangular forms extending along both sides of the rectangle portion, a central rectangular form, and a form including a central rectangle and a rectangular ring surrounding the central rectangle.

4. The semiconductor device of claim 1, wherein at least one interlayer insulating layer is disposed between the at least one wiring layer and the insulating layer, and a first interlayer insulating layer contacting the insulating layer has an etch selectivity different than an etch sensitivity of the insulating layer.

5. The semiconductor device of claim 4, wherein when the insulating layer is an oxide layer, the first interlayer insulating layer is a nitride layer, and when the insulating layer is a nitride layer, the first interlayer insulating layer is an oxide layer.

6. The semiconductor device of claim 1, wherein a bottom surface of the TSV faces in a same direction as the back side of the substrate and is exposed at the first portion; and
at least one of a pad and a bump are disposed on the bottom surface of the TSV.

7. The semiconductor device of claim 6, wherein a bottom surface of the insulating layer facing the same direction as the back side of the substrate and the bottom surface of the TSV form a same plane.

8. The semiconductor device of claim 1, wherein a bottom surface of the TSV faces a same direction as the back side of the substrate and is exposed at the first portion;
a pad and a bump are disposed on the insulating layer at a portion spaced a predetermined distance apart from a bottom surface of the TSV; and
the pad and the bottom surface of the TSV are connected to each other through a rewiring line.

9. The semiconductor device of claim 8, wherein a resist layer covering the rewiring line and exposing the bump is formed on the insulating layer.

10. The semiconductor device of claim 1, wherein the second portion of the insulating layer serves as a protective layer protecting the back side of the substrate of the non-recess region.

11. A semiconductor package comprising:
a first semiconductor chip comprising the semiconductor device of claim 1;
at least one second semiconductor chip stacked on the first semiconductor chip; and
a sealing material sealing the first semiconductor chip and the at least one second semiconductor chip,
wherein the TSV is electrically connected to the at least one second semiconductor chip.

12. The semiconductor package of claim 11, wherein the at least one second semiconductor chip is provided in plurality, and the TSV is formed in a remaining second semiconductor chip except the uppermost second semiconductor chip among the at least one semiconductor chip provided in plurality.

13. The semiconductor package of claim 11, wherein
an electrode pad is formed in the first semiconductor chip;
an external connection member is disposed on the electrode pad; and
the first semiconductor chip is mounted on a main chip or a package substrate, which supports the semiconductor package, through the external connection member.

14. A semiconductor device comprising:
a substrate having a front side and a back side and comprising a recess region in a predetermined portion of the back side;
an insulating layer filling in the recess region and covering an entirety of the back side of the substrate; and
a plurality of TSVs formed by penetrating the insulating layer in the recess region, electrically insulated from the substrate, and electrically connected to a wiring layer on the substrate.

15. The semiconductor device of claim 14, wherein a barrier layer is formed between the plurality of TSVs and the insulating layer.

16. A semiconductor device comprising:
a substrate having a region of silicon layer and a region of insulating layer;
a plurality of TSVs surrounded by the insulating layer; and
a wiring part disposed on the region of silicon layer and the region of insulating layer, and including at least one wiring layer electrically connected to the plurality of TSVs.

17. The semiconductor device of claim 16, wherein only the insulting layer is between two adjacent TSVs.

18. The semiconductor device of claim 16, wherein each of the plurality of TSVs includes a center metallic layer and a seed metallic layer surrounding the center metallic layer, and the seed metallic layer is surrounded by the insulting layer.

19. The semiconductor device of claim 16, wherein a barrier layer is formed between each of the plurality of TSVs and the insulating layer.

20. The semiconductor device of claim 16, wherein the substrate has a rectangle portion that is horizontally shaped; and
a horizontal section of the region of insulating layer has one of a rectangular ring form surrounding an outer border portion of the rectangle portion, an elongated rectangular form extending from a center portion of the rectangle portion, two elongated rectangular forms extending along both sides of the rectangle portion, a central rectangular form, and a form including a central rectangle and a rectangular ring surrounding the central rectangle.
